(19) United States
(12) Patent Application Publication
(10) Pub. No.: US 2025/0218771 A1
(43) Pub. Date: Jul. 3, 2025

(54) SILICON CARBIDE EPITAXIAL SUBSTRATE AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventors: Hideyuki HISANABE, Osaka (JP); Taro ENOKIZONO, Osaka (JP); Naoki OKAYAMA, Osaka (JP)

(73) Assignee: SUMITOMO ELECTRIC INDUSTRIES, LTD., Osaka (JP)

(21) Appl. No.: 18/844,214

(22) PCT Filed: Mar. 9, 2023
(86) PCT No.: PCT/JP2023/009018

§ 371 Date: Sep. 5, 2024

(30) Foreign Application Priority Data
Mar. 17, 2022 (JP) 2022-042485

(51) Int. Cl. H01L 21/02; C30B 25/20; C30B 29/36; H10D 62/40; H10D 62/53; H10D 62/57; H10D 62/832

(52) U.S. Cl. CPC H01L 21/02529; C30B 25/20; C30B 29/36; H01L 21/02378; H01L 21/02433; H01L 21/02609; H10D 62/405; H10D 62/53; H10D 62/57; H10D 62/8325

(57) ABSTRACT

A silicon carbide epitaxial substrate has a silicon carbide substrate, a silicon carbide epitaxial layer, an internal line-shaped stacking fault, and a carrot defect. The silicon carbide epitaxial layer is located on the silicon carbide substrate and has a main surface. The internal line-shaped stacking fault is located inside the silicon carbide epitaxial layer and is separated from the main surface. The carrot defect is exposed at the main surface. A value obtained by dividing a length of the internal line-shaped stacking fault by a width of the internal line-shaped stacking fault is 0.5 or less. A value obtained by dividing a length of the carrot defect by a width of the carrot defect is more than 0.5. The number of the internal line-shaped stacking faults is less than the number of the carrot defects.

### TECHNICAL FIELD

The present disclosure relates to a silicon carbide epitaxial substrate and a method of manufacturing a silicon carbide semiconductor device. The present application claims priority based on Japanese Patent Application No. 2022-042485 filed on Mar. 17, 2022. The entire contents of the Japanese Patent Application are incorporated herein by reference.

### BACKGROUND ART

Japanese Patent Laying-Open No. 2018-113303 (PTL 1) describes a silicon carbide epitaxial wafer in which a density of an internal 3C triangular defect is 0.1/cm² or less.

### CITATION LIST

### Patent Literature

PTL 1: Japanese Patent Laying-Open No. 2018-113303

### SUMMARY OF INVENTION

A silicon carbide epitaxial substrate according to the present disclosure includes a silicon carbide substrate, a silicon carbide epitaxial layer, an internal line-shaped stacking fault, and a carrot defect. The silicon carbide epitaxial layer is located on the silicon carbide substrate and has a main surface. The internal line-shaped stacking fault is located inside the silicon carbide epitaxial layer and is separated from the main surface. The carrot defect is exposed at the main surface. The main surface is a plane inclined with respect to a {0001} plane. A length of the carrot defect in a <1-100> direction is defined as a first length, a width of the carrot defect in a <11-20> direction is defined as a first width, a length of the internal line-shaped stacking fault in the <1-100> direction is defined as a second length, and a width of the internal line-shaped stacking fault in the <11-20> direction is defined as a second width as viewed in a direction perpendicular to the main surface. A value obtained by dividing the first length by the first width is more than 0.5. A value obtained by dividing the second length by the second width is 0.5 or less. The number of the internal line-shaped stacking faults is less than the number of the carrot defects.

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view along a line II-II of FIG. 1.

FIG. 3 is an enlarged schematic plan view of a region III in FIG. 1.

FIG. 4 is a schematic cross sectional view along a line IV-IV of FIG. 3.

FIG. 5 is an enlarged schematic plan view of a region V in FIG. 1.

FIG. 6 is a schematic cross sectional view along a line VI-VI of FIG. 5.

FIG. 7 is a schematic diagram showing a configuration of a color photoluminescence imaging device.

FIG. 8 is a partial schematic cross sectional view showing a configuration of a manufacturing apparatus for the silicon carbide epitaxial substrate.

FIG. 9 is a schematic diagram showing a relation between a time and a propane flow rate with respect to a temperature.

FIG. 10 is a schematic diagram showing a relation between a time and a propane flow rate with respect to a hydrogen flow rate.

FIG. 11 is a flowchart schematically showing a method of manufacturing a silicon carbide semiconductor device according to the present embodiment.

FIG. 12 is a schematic cross sectional view showing a step of forming a body region.

FIG. 13 is a schematic cross sectional view showing a step of forming a source region.

FIG. 14 is a schematic cross sectional view showing a step of forming a trench in a first main surface of a silicon carbide epitaxial layer.

FIG. 15 is a schematic cross sectional view showing a step of forming a gate insulating film.

FIG. 16 is a schematic cross sectional view showing a step of forming a gate electrode and an interlayer insulating film.

FIG. 17 is a schematic cross sectional view showing a configuration of the silicon carbide semiconductor device according to the present embodiment.

FIG. 18 shows a transmission electron microscope (TEM) image of a silicon carbide epitaxial substrate according to an example of the present disclosure.

### DETAILED DESCRIPTION

### Problem to be Solved by the Present Disclosure

An object of the present disclosure is to provide a silicon carbide epitaxial substrate and a method of manufacturing a silicon carbide semiconductor device so as to attain improved reliability of the silicon carbide semiconductor device.

### Advantageous Effect of the Present Disclosure

According to the present disclosure, it is possible to provide a silicon carbide epitaxial substrate and a method of manufacturing a silicon carbide semiconductor device so as to attain improved reliability of the silicon carbide semiconductor device.

### Description of Embodiments

First, an overview of an embodiment of the present disclosure will be described. Regarding crystallographic indications in the present specification, an individual orientation is represented by [ ], a group orientation is represented by < >, and an individual plane is represented by ( ) and a group plane is represented by { }. A crystallographically negative index is normally expressed by putting “−” (bar) above a numeral; however, in the present specification, the crystallographically negative index is expressed by putting a negative sign before the numeral.

(1) A silicon carbide epitaxial substrate 100 according to the present disclosure includes a silicon carbide substrate 30, a silicon carbide epitaxial layer 40, an internal line-shaped stacking fault 10, and a carrot defect 20. Silicon carbide epitaxial layer 40 is located on silicon carbide substrate 30 and has a main surface 1. Internal line-shaped stacking fault 10 is located inside silicon carbide epitaxial layer 40 and is separated from main surface 1. Carrot defect 20 is exposed at main surface 1. Main surface 1 is a plane inclined with respect to a {0001} plane. A length of carrot defect 20 in a <1-100> direction is defined as a first length B1, a width of carrot defect 20 in a <11-20> direction is defined as a first width A1, a length of internal line-shaped stacking fault 10 in the <1-100> direction is defined as a second length B2, and a width of internal line-shaped stacking fault 10 in the <11-20> direction is defined as a second width A2 as viewed in a direction perpendicular to main surface 1. A value obtained by dividing first length B1 by first width A1 is more than 0.5. A value obtained by dividing second length B2 by second width A2 is 0.5 or less. The number of internal line-shaped stacking faults 10 is less than the number of carrot defects 20.

(2) According to silicon carbide epitaxial substrate 100 according to (1), when photoluminescence light generated from internal line-shaped stacking fault 10 by applying excitation light to internal line-shaped stacking fault 10 is expressed in an HSV color space, H may be 150° or more and 220° or less, S may be 30 or more and 100 or less, and V may be 205 or more and 255 or less.

(3) According to silicon carbide epitaxial substrate 100 according to (1) or (2), when photoluminescence light generated from carrot defect 20 by applying excitation light to carrot defect 20 is expressed in an HSV color space, H may be 80° or more and 235° or less, S may be 25 or more and 90 or less, and V may be 180 or more and 255 or less.

(4) According to silicon carbide epitaxial substrate 100 according to any one of (1) to (3), a value obtained by dividing the number of internal line-shaped stacking faults 10 by the number of carrot defects 20 may be 0.55 or less.

(5) According to silicon carbide epitaxial substrate 100 according to any one of (1) to (4), main surface 1 may be a plane inclined with respect to a (000-1) plane.

(6) According to silicon carbide epitaxial substrate 100 according to (5), an off angle of the main surface with respect to the (000-1) plane may be more than 0° and 8° or less.

(7) According to silicon carbide epitaxial substrate 100 according to any one of (1) to (6), internal line-shaped stacking fault 10 may extend in a form of a line from a first end portion 11 toward a second end portion 12 opposite to first end portion 11 as viewed in the direction perpendicular to main surface 1. A length of first end portion 11 in the <1-100> direction may be 0.8 times or more and 1.2 times or less as large as a length of second end portion 12 in the <1-100> direction.

(8) According to silicon carbide epitaxial substrate 100 according to any one of (1) to (7), when measured by a white light microscope, a step of a portion of the main surface that internal line-shaped stacking fault 10 faces may be 9 nm or less.

(9) According to silicon carbide epitaxial substrate 100 of any one of (1) to (8), internal line-shaped stacking fault 10 may have an upper end surface 15 facing main surface 1. A distance between main surface 1 and upper end surface 15 may be 0.1 μm or more in the direction perpendicular to main surface 1.

(10) According to silicon carbide epitaxial substrate 100 according to (9), a region between main surface 1 and upper end surface 15 may be a region having a polytype of 4H.

(11) According to silicon carbide epitaxial substrate 100 according to any one of (1) to (10), internal line-shaped stacking fault 10 may include a Frank-type fault.

(12) According to silicon carbide epitaxial substrate 100 according to any of (1) to (11), silicon carbide epitaxial layer 40 may have a polytype of 4H.

(13) A method of manufacturing a silicon carbide semiconductor device according to the present disclosure includes the following steps. Silicon carbide epitaxial substrate 100 according to any one of (1) to (12) is prepared. Silicon carbide epitaxial substrate 100 is processed.

### Details of Embodiments of the Present Disclosure

Hereinafter, embodiments of the present disclosure will be described in detail. In the description below, the same or corresponding elements are denoted by the same reference characters and will not be described repeatedly.

### (Silicon Carbide Epitaxial Substrate)

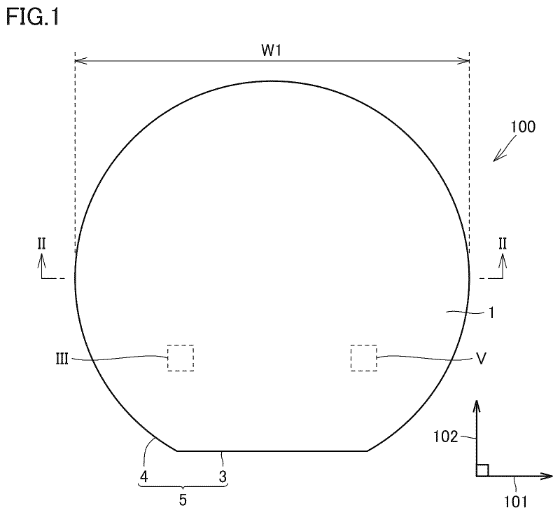

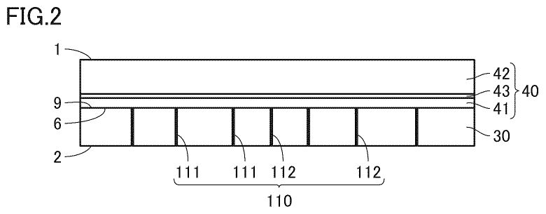

FIG. 1 is a schematic plan view showing a configuration of a silicon carbide epitaxial substrate 100 according to the present embodiment. FIG. 2 is a schematic cross sectional view along a line II-II of FIG. 1. As shown in FIGS. 1 and 2, silicon carbide epitaxial substrate 100 according to the present embodiment has a silicon carbide substrate 30 and a silicon carbide epitaxial layer 40. Silicon carbide epitaxial layer 40 is located on silicon carbide substrate 30. Silicon carbide epitaxial layer 40 is in contact with silicon carbide substrate 30. Silicon carbide epitaxial layer 40 has a first main surface 1.

Silicon carbide epitaxial layer 40 constitutes a front surface (first main surface 1) of silicon carbide epitaxial substrate 100. Silicon carbide substrate 30 constitutes a backside surface (second main surface 2) of silicon carbide epitaxial substrate 100. As shown in FIG. 1, silicon carbide epitaxial substrate 100 has an outer peripheral edge 5. Outer peripheral edge 5 has, for example, an orientation flat 3 and an arc-shaped portion 4. Orientation flat 3 extends along a first direction 101. As shown in FIG. 1, orientation flat 3 is in the form of a straight line as viewed in a direction perpendicular to first main surface 1. Arc-shaped portion 4 is contiguous to orientation flat 3. Arc-shaped portion 4 has an arc shape as viewed in the direction perpendicular to first main surface 1.

As shown in FIG. 1, as viewed in the direction perpendicular to first main surface 1, first main surface 1 is expanded along each of first direction 101 and a second direction 102. As viewed in the direction perpendicular to first main surface 1, first direction 101 is a direction perpendicular to second direction 102.

First direction 101 is, for example, a <11-20> direction. First direction 101 may be, for example, a [11-20] direction. First direction 101 may be a direction obtained by projecting the <11-20> direction onto first main surface 1. From another viewpoint, it can be said that first direction 101 may be a direction including a <11-20> direction component, for example.

Second direction 102 is, for example, a <1-100> direction. Second direction 102 may be, for example, a [1-100] direction. Second direction 102 may be, for example, a direction obtained by projecting the <1-100> direction onto first main surface 1. From another viewpoint, it can be said that second direction 102 may be a direction including a <1-100> direction component, for example.

First main surface 1 is a plane inclined with respect to a {0001} plane. An inclination angle (off angle θ) thereof with respect to the {0001} plane is, for example, 8° or less rather than 0°. Off angle θ is not particularly limited, but may be, for example, 1° or more or 2° or more. Off angle θ is not particularly limited, but may be, for example, 7° or less or 6° or less. First main surface 1 may be a plane inclined by off angle θ with respect to a (000-1) plane, or may be a plane inclined by off angle θ with respect to a (0001) plane. An inclination direction (off direction) of first main surface 1 is, for example, the <11-20> direction. From another viewpoint, it can be said that first direction 101 may be the off direction of first main surface 1.

As shown in FIG. 1, maximum diameter W1 (diameter) of first main surface 1 is not particularly limited, but is, for example, 100 mm (4 inches). Maximum diameter W1 may be 125 mm (5 inches) or more, or 150 mm (6 inches) or more. Maximum diameter W1 is not particularly limited. Maximum diameter W1 may be, for example, 200 mm (8 inches) or less. Maximum diameter W1 is the maximum distance between any two points on outer peripheral edge 5.

It should be noted that in the present specification, 4 inches mean 100 mm or 101.6 mm (4 inches×25.4 mm/inch). 6 inches mean 150 mm or 152.4 mm (6 inches×25.4 mm/inch). 8 inches mean 200 mm or 203.2 mm (8 inches×25.4 mm/inch).

As shown in FIG. 2, silicon carbide substrate 30 includes a plurality of threading screw dislocations 110. The plurality of threading screw dislocations 110 have a plurality of first threading screw dislocations 111 and a plurality of second threading screw dislocations 112. Silicon carbide substrate 30 has second main surface 2 and a third main surface 9. Third main surface 9 is located opposite to second main surface 2. Second main surface 2 is the backside surface of silicon carbide epitaxial substrate 100. Second main surface 2 is separated from silicon carbide epitaxial layer 40. Third main surface 9 is in contact with silicon carbide epitaxial layer 40. Silicon carbide substrate 30 has a polytype of, for example, 4H. Similarly, silicon carbide epitaxial layer 40 has a polytype of, for example, 4H.

As shown in FIG. 2, silicon carbide epitaxial layer 40 has a fourth main surface 6. Fourth main surface 6 is in contact with silicon carbide substrate 30. Silicon carbide epitaxial layer 40 includes a buffer layer 41, a transition layer 43, and a drift layer 42. Drift layer 42 may be a single layer or two or more layers. Buffer layer 41 is located on silicon carbide substrate 30. Buffer layer 41 is in contact with silicon carbide substrate 30. Transition layer 43 is located on buffer layer 41. Transition layer 43 is in contact with buffer layer 41. Drift layer 42 is located on transition layer 43. Drift layer 42 is in contact with transition layer 43. The drift layer constitutes first main surface 1. The buffer layer constitutes fourth main surface 6.

Silicon carbide substrate 30 includes an n type impurity such as nitrogen (N), for example. The conductivity type of silicon carbide substrate 30 is, for example, n type. The thickness of silicon carbide substrate 30 is 200 μm or more and 600 μm or less, for example. Silicon carbide epitaxial layer 40 includes an n type impurity such as nitrogen, for example. The conductivity type of silicon carbide epitaxial layer 40 is, for example, n type.

The concentration of the n type impurity included in buffer layer 41 may be lower than the concentration of the n type impurity included in silicon carbide substrate 30. The concentration of the n type impurity included in drift layer 42 may be lower than the concentration of the n type impurity included in buffer layer 41. The concentration of the n type impurity included in transition layer 43 may be lower than the concentration of the n type impurity included in buffer layer 41 and may be higher than the concentration of the n type impurity included in drift layer 42.

The concentration of the n type impurity included in transition layer 43 may be monotonously decreased in a direction from buffer layer 41 toward drift layer 42. The concentration of the n type impurity included in drift layer 42 is, for example, about 1×10¹⁴ cm⁻³ or more and 1×10¹⁷ cm⁻³ or less. The concentration of the n type impurity included in buffer layer 41 is, for example, about 1×10¹⁸ cm⁻³ or more and 1×10¹⁹ cm⁻³ or less.

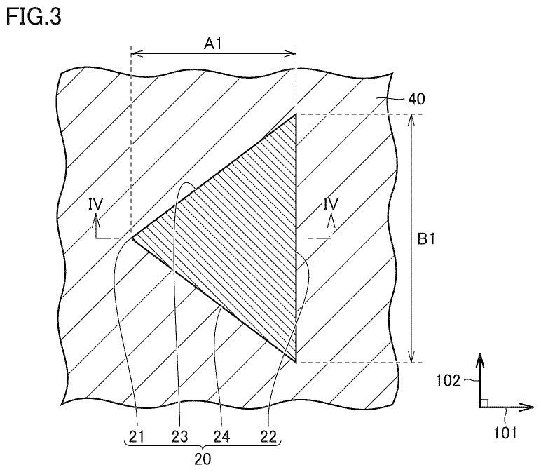

FIG. 3 is an enlarged schematic plan view of a region III in FIG. 1. The enlarged schematic plan view shown in FIG. 3 shows a state observed by a color photoluminescence imaging device. As shown in FIG. 3, silicon carbide epitaxial substrate 100 according to the present embodiment has a carrot defect 20. As shown in FIG. 3, carrot defect 20 has, for example, a triangular shape as viewed in the direction perpendicular to first main surface 1. Carrot defect 20 is, for example, a stacking fault.

As shown in FIG. 3, the width of carrot defect 20 in the <11-20> direction (first direction 101) is defined as a first width A1 as viewed in the direction perpendicular to first main surface 1. The length of carrot defect 20 in the <1-100> direction (second direction 102) is defined as a first length B1 as viewed in the direction perpendicular to first main surface 1. A value obtained by dividing first length B1 by first width A1 is more than 0.5.

The value obtained by dividing first length B1 by first width A1 is not particularly limited, but may be more than 0.75 or more than 1, for example. The value obtained by dividing first length B1 by first width A1 is not particularly limited, but may be 2 or less or 1.5 or less, for example.

As shown in FIG. 3, carrot defect 20 has an apex portion 21, a first side portion 23, a second side portion 24, and a bottom side portion 22. Each of first side portion 23 and second side portion 24 is contiguous to apex portion 21. The two side portions, i.e., first side portion 23 and second side portion 24 are branched from apex portion 21. Bottom side portion 22 is contiguous to each of first side portion 23 and second side portion 24. First side portion 23 is contiguous to one end of bottom side portion 22, and second side portion 24 is contiguous to the other end of bottom side portion 22.

As viewed in the direction perpendicular to first main surface 1, first side portion 23 is inclined with respect to each of first direction 101 and second direction 102. First side portion 23 may be inclined to second direction 102 with respect to a straight line parallel to first direction 101. Second side portion 24 may be inclined, with respect to the straight line parallel to first direction 101, to a side opposite to second direction 102. As viewed in the direction perpendicular to first main surface 1, bottom side portion 22 extends along second direction 102. Second length B2 may be equal to the length of bottom side portion 22. As viewed in the direction perpendicular to first main surface 1, the length of carrot defect 20 in second direction 102 may be increased in a direction from apex portion 21 toward bottom side portion 22.

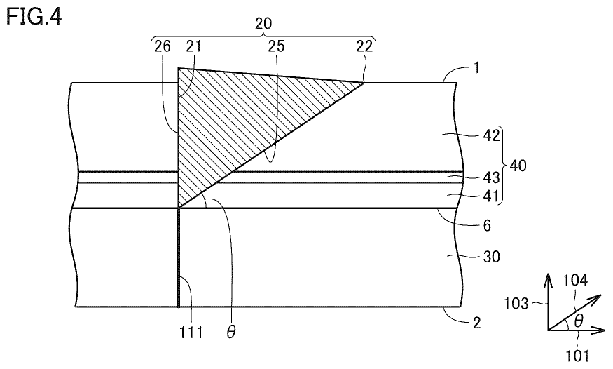

FIG. 4 is a schematic cross sectional view along a line IV-IV of FIG. 3. The cross section shown in FIG. 4 is a cross section perpendicular to first main surface 1. As shown in FIG. 4, carrot defect 20 may result from first threading screw dislocation 111. Specifically, carrot defect 20 may be contiguous to first threading screw dislocation 111. Carrot defect 20 may have a bottom surface portion 25.

Bottom surface portion 25 is contiguous to first threading screw dislocation 111. Bottom surface portion 25 extends along a fourth direction 104. A plane extending along fourth direction 104 is a basal plane. Bottom surface portion 25 extends through each of buffer layer 41, transition layer 43, and drift layer 42. Bottom surface portion 25 extends from fourth main surface 6 to first main surface 1. Bottom surface portion 25 may be contiguous to bottom side portion 22 at first main surface 1. A third direction 103 is a direction perpendicular to each of first direction 101 and second direction 102. Fourth direction 104 is inclined with respect to each of first direction 101 and third direction 103.

Carrot defect 20 may have a side surface portion 26. Side surface portion 26 is contiguous to first threading screw dislocation 111. Side surface portion 26 extends along first threading screw dislocation 111. Bottom surface portion 25 extends through each of buffer layer 41, transition layer 43, and drift layer 42. Bottom surface portion 25 is contiguous to apex portion 21.

As shown in FIG. 4, carrot defect 20 is exposed at first main surface 1. Carrot defect 20 protrudes. Therefore, carrot defect 20 can be specified by observing first main surface 1 of silicon carbide epitaxial substrate 100 using a defect inspection apparatus having a confocal differential interference microscope, for example.

As the defect inspection apparatus having a confocal differential interference microscope, for example, WASAVI series “SICA 6X” provided by Lasertec can be used. The magnification of its objective lens is, for example, 10 times. Light having a wavelength of 546 nm is applied from a light source such as a mercury xenon lamp to first main surface 1 of silicon carbide epitaxial substrate 100, and reflected light thereof is observed by a light receiving element. A threshold value, which is an index of measurement sensitivity of the SICA, is Thresh S40, for example.

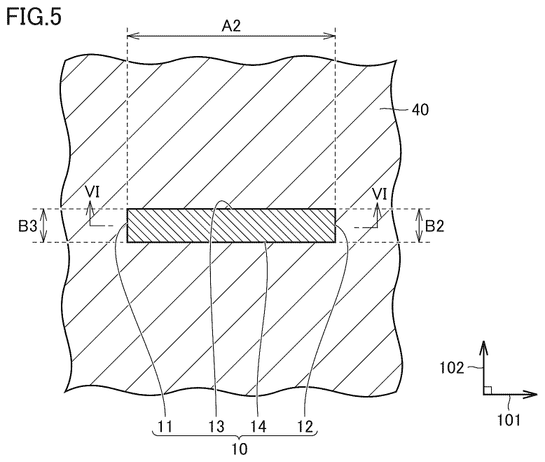

FIG. 5 is an enlarged schematic plan view of a region V in FIG. 1. The enlarged schematic plan view shown in FIG. 5 shows a state observed by a color photoluminescence imaging device. As shown in FIG. 5, silicon carbide epitaxial substrate 100 according to the present embodiment has internal line-shaped stacking fault 10. As shown in FIG. 5, internal line-shaped stacking fault 10 has, for example, an elongated rectangular shape as viewed in the direction perpendicular to first main surface 1. As viewed in the direction perpendicular to first main surface 1, the internal line-shaped fault extends along first direction 101.

As shown in FIG. 5, the width of internal line-shaped stacking fault 10 in the <11-20> direction (first direction 101) is defined as a second width A2 as viewed in the direction perpendicular to first main surface 1. The length of internal line-shaped stacking fault 10 in the <1-100> direction (second direction 102) is defined as a second length B2 as viewed in the direction perpendicular to first main surface 1. A value obtained by dividing second length B2 by second width A2 is 0.5 or less. The value obtained by dividing second length B2 by second width A2 is not particularly limited, but may be 0.05 or more or 0.1 or more, for example. The value obtained by dividing second length B2 by second width A2 is not particularly limited, but may be 0.35 or less or 0.25 or less, for example.

Internal line-shaped stacking fault 10 has a first end portion 11, a second end portion 12, a third end portion 13, and a fourth end portion 14. Second end portion 12 is located opposite to first end portion 11. As viewed in the direction perpendicular to first main surface 1, each of first end portion 11 and second end portion 12 extends along the <1-100> direction. Fourth end portion 14 is located opposite to third end portion 13. As viewed in the direction perpendicular to first main surface 1, each of third end portion 13 and fourth end portion 14 extends along the <11-20> direction.

First end portion 11 is contiguous to each of third end portion 13 and fourth end portion 14. Similarly, second end portion 12 is contiguous to each of third end portion 13 and fourth end portion 14. As viewed in the direction perpendicular to first main surface 1, internal line-shaped stacking fault 10 extends in the form of a line from first end portion 11 toward second end portion 12. As viewed in the direction perpendicular to first main surface 1, the length (third length B3) of first end portion 11 in the <1-100> direction may be 0.8 times or more and 1.2 times or less as large as the length (second length B2) of second end portion 12 in the <1-100> direction.

As viewed in the direction perpendicular to first main surface 1, the length of first end portion 11 in the <1-100> direction may be 0.85 times or more or 0.9 times or more as large as the length of second end portion 12 in the <1-100> direction. As viewed in the direction perpendicular to first main surface 1, the length of first end portion 11 in the <1-100> direction may be 1.15 times or less or 1.1 times or less as large as the length of second end portion 12 in the <1-100> direction.

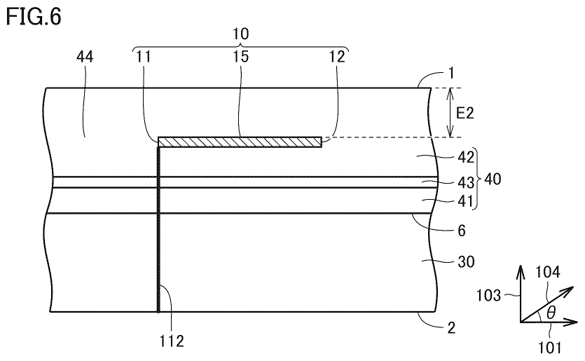

FIG. 6 is a schematic cross sectional view along a line VI-VI of FIG. 5. The cross section shown in FIG. 6 is a cross section perpendicular to first main surface 1. As shown in FIG. 6, internal line-shaped stacking fault 10 may result from a second threading screw dislocation 112 of the plurality of threading screw dislocations 110. Specifically, internal line-shaped stacking fault 10 may be contiguous to second threading screw dislocation 112. Internal line-shaped stacking fault 10 includes, for example, a Frank-type fault.

Whether or not internal line-shaped stacking fault 10 includes a Frank-type fault can be determined using a transmission electron microscope. Specifically, a cross sectional high-resolution image of a partial dislocation attached to an edge of internal line-shaped stacking fault 10 is observed using the transmission electron microscope. Measurement conditions for the cross sectional high-resolution image are as follows. An electron beam acceleration voltage is 200 keV. An observation sample thickness is 100 nm. It is specified whether the number of (0004) planes is increased, is decreased, or is the same between a stacking fault portion and a completely crystal portion. When the number of (0004) planes in the stacking fault portion is increased or decreased with respect to the number of (0004) planes in the completely crystal portion, it is determined that internal line-shaped stacking fault 10 includes the Frank-type fault. On the other hand, when the number of (0004) planes is the same between the stacking fault portion and the completely crystal portion, it is determined that internal line-shaped stacking fault 10 includes no Frank-type fault.

Internal line-shaped stacking fault 10 is located inside silicon carbide epitaxial layer 40. Internal line-shaped stacking fault 10 is separated from first main surface 1. Internal line-shaped stacking fault 10 has an upper end surface 15 facing first main surface 1. Upper end surface 15 is located between first end portion 11 and second end portion 12. Upper end surface 15 may extend along first direction 101. A region between first main surface 1 and upper end surface 15 is a region 44 having a polytype of 4H. Internal line-shaped stacking fault 10 is surrounded by region 44 having a polytype of 4H. Internal line-shaped stacking fault 10 may be located inside buffer layer 41, may be located inside transition layer 43, or may be located inside drift layer 42.

In the direction perpendicular to first main surface 1, a distance E2 between first main surface 1 and upper end surface 15 is, for example, 0.1 μm or more. Distance E2 between first main surface 1 and upper end surface 15 is not particularly limited, but may be, for example, 0.2 μm or more or 0.3 μm or more. Distance E2 between first main surface 1 and upper end surface 15 is not particularly limited, but may be, for example, 10 μm or less or 5 μm or less.

As shown in FIG. 6, internal line-shaped stacking fault 10 is not exposed at first main surface 1. A portion of first main surface 1 facing upper end surface 15 of internal line-shaped stacking fault 10 does not protrude. Specifically, when measured with a white light microscope, a step of the portion of first main surface 1 that internal line-shaped stacking fault 10 faces is, for example, 9 nm or less. The step of the portion of first main surface 1 that internal line-shaped stacking fault 10 faces may be, for example, 7 nm or less, 5 nm or less, 3 nm or less, or 1 nm or less. As the white light microscope, a white light interferometric microscope provided by Nikon (model number: Nikon BW-503D) may be used. Since substantially no step is formed in the portion of first main surface 1 that internal line-shaped stacking fault 10 faces, internal line-shaped stacking fault 10 cannot be substantially specified using the white light interferometric microscope. On the other hand, as described above, internal line-shaped stacking fault 10 can be specified by a color photoluminescence imaging device.

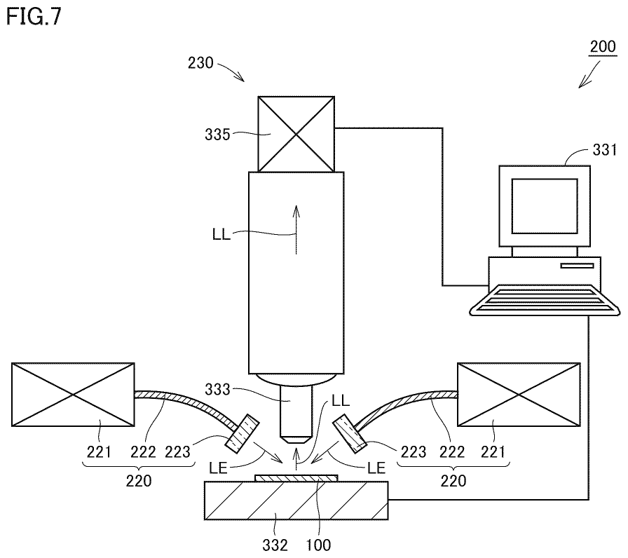

FIG. 7 is a schematic diagram showing a configuration of the color photoluminescence imaging device. As the color photoluminescence imaging device, for example, a PL imaging device (SemiScope PLI-200) provided by PHOTON Design Corporation can be used. As shown in FIG. 7, a color photoluminescence imaging device 200 mainly has an excitation light generation unit 220 and an imaging unit 230.

Excitation light generation unit 220 has a light source unit 221, a light guide unit 222, and a filter unit 223. Light source unit 221 can generate excitation light LE having an energy higher than a band gap of a hexagonal silicon carbide. Light source unit 221 is, for example, a mercury xenon lamp. Light guide unit 222 can guide the light emitted from light source unit 221 so as to apply the light to first main surface 1 of silicon carbide epitaxial substrate 100. Light guide unit 222 has, for example, an optical fiber. As shown in FIG. 7, excitation light generation unit 220 may be disposed on each of both sides with respect to a near-infrared objective lens 333.

Filter unit 223 selectively allows for passing of light having a specific wavelength corresponding to the energy higher than the band gap of the hexagonal silicon carbide. The wavelength corresponding to the band gap of the hexagonal silicon carbide is typically about 390 nm. Therefore, for example, a band-pass filter that particularly allows for passing of light having a wavelength of about 313 nm is used as filter unit 223. A passing wavelength range of filter unit 223 may be, for example, 290 nm or more and 370 nm or less, 300 nm or more and 330 nm or less, or 300 nm or more and 320 nm or less.

Imaging unit 230 mainly has a control unit 331, a stage 332, near-infrared objective lens 333, and a color image sensor 335. Control unit 331 controls a position changing operation of stage 332 and an imaging operation by color image sensor 335, and is, for example, a personal computer. Stage 332 supports silicon carbide epitaxial substrate 100 so as to expose first main surface 1. Stage 332 is, for example, an XY stage that changes the position of first main surface 1. Near-infrared objective lens 333 is disposed above first main surface 1. The magnification of near-infrared objective lens 333 is, for example, 4.5 times. Color image sensor 335 receives the photoluminescence light emitted from silicon carbide epitaxial substrate 100.

Next, a method of specifying each of carrot defect 20 and internal line-shaped stacking fault 10 will be described.

First, excitation light generation unit 220 is used to apply excitation light LE to first main surface 1 of silicon carbide epitaxial substrate 100. Thus, photoluminescence light LL is generated from silicon carbide epitaxial substrate 100. The wavelength of excitation light LE is, for example, 313 nm. The intensity of excitation light LE is, for example, 1 mW/cm² or more and 2 W/cm² or less. The exposure time of the applied light is, for example, 0.5 seconds or more and 120 seconds or less. The measurement temperature is, for example, a room temperature (24° C.).

Next, the photoluminescence light is detected by the color image sensor. Specifically, photoluminescence light LL generated in silicon carbide epitaxial substrate 100 is detected by color image sensor 335. Color image sensor 335 is, for example, a CCD (charge-coupled device) image sensor. The CCD element is of, for example, a back-illuminated deep depletion type. The CCD image sensor is, for example, eXcelon (trademark) provided by Teledyne. An imaging wavelength range is, for example, 310 nm or more and 1024 nm or less. An element format is, for example, 1024ch×1024ch. An image area is, for example, 13.3 mm×13.3 mm. An element size is, for example, 13 μm×13 μm. The number of pixels is, for example, 480 pixels×640 pixels. An image size is, for example, 1.9 mm×2.6 mm.

Based on the color image obtained from the color image sensor, an optical property of each of carrot defect 20 and internal line-shaped stacking fault 10 is specified. The color of the image of carrot defect 20 obtained from the color image sensor is, for example, blue. Specifically, when the photoluminescence light generated from carrot defect 20 by applying the excitation light to carrot defect 20 is expressed in an HSV color space, H is 80° or more and 235° or less, S is 25 or more and 90 or less, and V is 180 or more and 255 or less.

The color of the image of internal line-shaped stacking fault 10 obtained from the color image sensor is, for example, blue. Specifically, when the photoluminescence light generated from internal line-shaped stacking fault 10 by applying the excitation light to internal line-shaped stacking fault 10 is expressed in the HSV color space, H is 150° or more and 220° or less, S is 30 or more and 100 or less, and V is 205 or more and 255 or less.

It should be noted that the HSV color space is one of color expression methods for expressing colors by hue, saturation and value. In the HSV color space, the range of H is 0° or more and 360° or less. The range of S is 0 or more and 255 or less. The range of V is 0 or more and 255 or less. Each of S and V is displayed in 256 gradations. The model of the HSV color space is a cylindrical model.

The number of internal line-shaped stacking faults 10 and the number of carrot defects 20 are found across a whole of first main surface 1. According to silicon carbide epitaxial substrate 100 of the present embodiment, the number of internal line-shaped stacking faults 10 is less than the number of carrot defects 20.

A value obtained by dividing the number of internal line-shaped stacking faults 10 by the number of carrot defects 20 may be, for example, 0.55 or less. The value obtained by dividing the number of internal line-shaped stacking faults 10 by the number of carrot defects 20 is not particularly limited, but may be, for example, 0.05 or more or 0.1 or more. The value obtained by dividing the number of internal line-shaped stacking faults 10 by the number of carrot defects 20 is not particularly limited, but may be, for example, 0.4 or less or 0.3 or less.

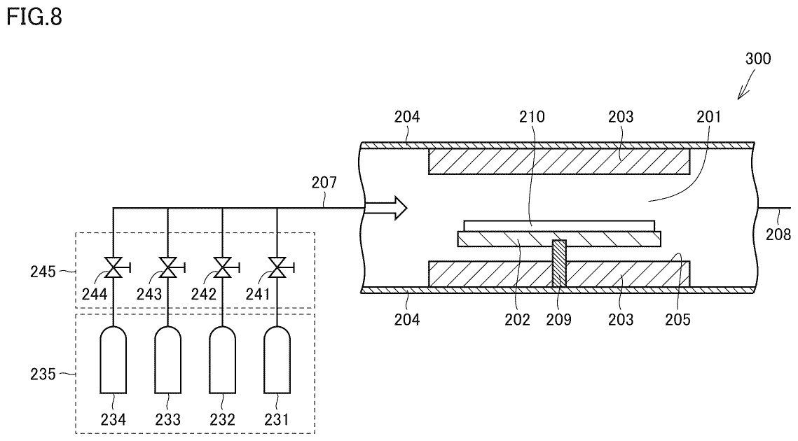

Next, a configuration of a manufacturing apparatus for silicon carbide epitaxial substrate 100 will be described. FIG. 8 is a partial schematic cross sectional view showing the configuration of the manufacturing apparatus for silicon carbide epitaxial substrate 100. A manufacturing apparatus 300 for silicon carbide epitaxial substrate 100 is, for example, a hot wall type lateral CVD (Chemical Vapor Deposition) apparatus. As shown in FIG. 8, manufacturing apparatus 300 for silicon carbide epitaxial substrate 100 mainly has a reaction chamber 201, a gas supply unit 235, a control unit 245, a heating element 203, a quartz tube 204, a heat insulating material (not shown), and an induction heating coil (not shown).

Heating element 203 has, for example, a tubular shape, and forms reaction chamber 201 therein. Heating element 203 is composed of graphite, for example. Heating element 203 is provided inside quartz tube 204. The heat insulating material surrounds the outer periphery of heating element 203. The induction heating coil is wound, for example, along the outer peripheral surface of quartz tube 204. The induction heating coil can be supplied with an alternating current by an external power supply (not shown). Thus, heating element 203 is inductively heated. As a result, reaction chamber 201 is heated by heating element 203.

Reaction chamber 201 is a formed space surrounded by an inner wall surface 205 of heating element 203. A susceptor 210 that holds silicon carbide substrate 30 is provided in reaction chamber 201. Susceptor 210 is composed of silicon carbide. Silicon carbide substrate 30 is placed on susceptor 210. Susceptor 210 is disposed on a stage 202. Stage 202 is rotatably supported by a rotation shaft 209. When stage 202 is rotated, susceptor 210 is rotated.

Manufacturing apparatus 300 for silicon carbide epitaxial substrate 100 further has a gas introduction port 207 and a gas discharging port 208. Gas discharging port 208 is connected to a gas discharging pump (not shown). An arrow in FIG. 8 indicates a flow of gas. The gas is introduced from gas introduction port 207 into reaction chamber 201 and is discharged from gas discharging port 208. Pressure in reaction chamber 201 is adjusted in accordance with a balance between an amount of supply of the gas and an amount of discharging of the gas.

Gas supply unit 235 is configured to supply reaction chamber 201 with a mixed gas including a source gas, a dopant gas, and a carrier gas. Specifically, gas supply unit 235 includes, for example, a first gas supply unit 231, a second gas supply unit 232, a third gas supply unit 233, and a fourth gas supply unit 234.

First gas supply unit 231 is configured to supply a first gas including carbon atoms, for example. First gas supply unit 231 is, for example, a gas cylinder provided with the first gas. The first gas is, for example, propane (C₃H₈) gas. The first gas may be, for example, methane (CH₄) gas, ethane (C₂H₆) gas, acetylene (C₂H₂) gas, or the like.

Second gas supply unit 232 is configured to supply a second gas including, for example, a silane gas. Second gas supply unit 232 is, for example, a gas cylinder provided with the second gas. The second gas is, for example, silane (SiH₄) gas. The second gas may be a mixed gas of the silane gas and a gas other than silane.

Third gas supply unit 233 is configured to supply a third gas including, for example, nitrogen atoms. Third gas supply unit 233 is, for example, a gas cylinder provided with the third gas. The third gas is a doping gas. The third gas is, for example, ammonia gas. The ammonia gas is more likely to be thermally decomposed than nitrogen gas having a triple bond.

Fourth gas supply unit 234 is configured to supply a fourth gas (carrier gas) such as hydrogen, for example. Fourth gas supply unit 234 is, for example, a gas cylinder provided with hydrogen. The fourth gas may be argon gas.

Control unit 245 is configured to control a flow rate of the mixed gas to be supplied from gas supply unit 235 to reaction chamber 201. Specifically, control unit 245 may include a first gas flow rate control unit 241, a second gas flow rate control unit 242, a third gas flow rate control unit 243, and a fourth gas flow rate control unit 244. Each control unit may be, for example, an MFC (Mass Flow Controller). Control unit 245 is disposed between gas supply unit 235 and gas introduction port 207.

### (Method of Manufacturing Silicon Carbide Epitaxial Substrate)

Next, a method of manufacturing silicon carbide epitaxial substrate 100 according to the present embodiment will be described.

First, silicon carbide substrate 30 is prepared. For example, a silicon carbide single crystal having a polytype of 4H is produced by a sublimation method. Next, the silicon carbide single crystal is sliced by, for example, a wire saw to prepare silicon carbide substrate 30. Silicon carbide substrate 30 includes, for example, an n type impurity such as nitrogen. The conductivity type of silicon carbide substrate 30 is n type, for example. Next, mechanical polishing is performed onto silicon carbide substrate 30. Next, chemical mechanical polishing is performed onto silicon carbide substrate 30.

Next, silicon carbide epitaxial layer 40 is formed on silicon carbide substrate 30. Specifically, silicon carbide epitaxial layer 40 is formed by epitaxial growth on third main surface 9 of silicon carbide substrate 30 using the hot wall type lateral CVD apparatus shown in FIG. 8. In the epitaxial growth, for example, silane (SiH₄) and propane (C₃H₈) are each used as the source gas, and hydrogen (H₂) is used as the carrier gas. The temperature of the epitaxial growth is, for example, about 1400° C. or more and 1700° C. or less. In the epitaxial growth, an n type impurity such as nitrogen is introduced into silicon carbide epitaxial layer 40.

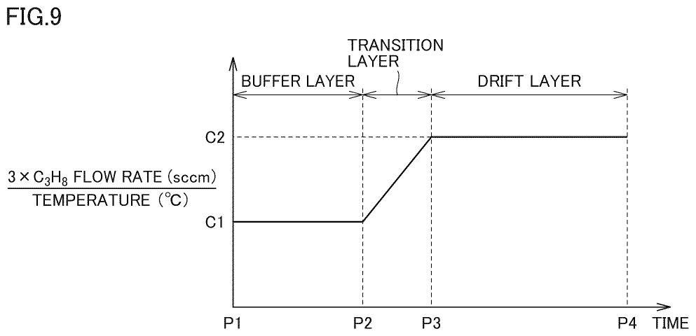

FIG. 9 is a schematic diagram showing a relation between a time and a propane flow rate with respect to the temperature. The propane flow rate with respect to the temperature is a value obtained by dividing 3×the propane flow rate (sccm) by the temperature (° C.). As shown in FIG. 9, at a first time point P1, the propane flow rate with respect to the temperature is set to a first ratio C1. During a period from first time point P1 to a second time point P2, the propane flow rate with respect to the temperature is maintained at first ratio C1. During the period from first time point P1 to second time point P2, buffer layer 41 is formed on silicon carbide substrate 30.

During a period from second time point P2 to a third time point P3, the propane flow rate with respect to the temperature is monotonously increased. During the period from second time point P2 to third time point P3, the propane flow rate with respect to the temperature is increased from first ratio C1 to a second ratio C2. During the period from second time point P2 to third time point P3, transition layer 43 is formed on buffer layer 41. During a period from third time point P3 to a fourth time point P4, the propane flow rate with respect to the temperature is maintained at second ratio C2. During the period from third time point P3 to fourth time point P4, drift layer 42 is formed on transition layer 43.

The propane flow rate with respect to the temperature is adjusted while changing each of the propane flow rate and the temperature. First ratio C1 is, for example, 0.034 (sccm/° C.). Second ratio C2 is, for example, 0.074 (sccm/° C.). A temperature at which drift layer 42 is formed may be higher than a temperature at which buffer layer 41 is formed. In the step of forming transition layer 43, the temperature may be increased. During the period from second time point P2 to third time point P3, the propane flow rate with respect to the temperature may be increased at a ratio of 0.0079 (sccm/° C.) per minute.

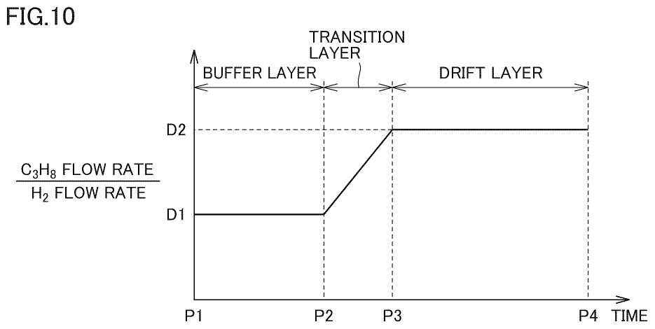

FIG. 10 is a schematic diagram showing a relation between the time and the propane flow rate with respect to a hydrogen flow rate. The propane flow rate with respect to the hydrogen flow rate is a value (dimensionless) obtained by dividing the propane flow rate by the hydrogen flow rate. As shown in FIG. 10, at first time point P1, the propane flow rate with respect to the hydrogen flow rate is set to a third ratio D1. During the period from first time point P1 to second time point P2, the propane flow rate with respect to the hydrogen flow rate is maintained at third ratio D1. During the period from first time point P1 to second time point P2, buffer layer 41 is formed on silicon carbide substrate 30.

During the period from second time point P2 to third time point P3, the propane flow rate with respect to the hydrogen flow rate is monotonously increased. During the period from second time point P2 to third time point P3, the propane flow rate with respect to the hydrogen flow rate is increased from third ratio D1 to a fourth ratio D2. During the period from second time point P2 to third time point P3, transition layer 43 is formed on buffer layer 41. During the period from third time point P3 to fourth time point P4, the propane flow rate with respect to the hydrogen flow rate is maintained at fourth ratio D2. During the period from third time point P3 to fourth time point P4, drift layer 42 is formed on transition layer 43.

During the period from first time point P1 to fourth time point P4, the hydrogen flow rate is, for example, 134 slm. The propane flow rate with respect to the hydrogen flow rate is adjusted, for example, by changing the propane flow rate while maintaining the hydrogen flow rate to be unchanged. Third ratio D1 is, for example, 0.000134. Fourth ratio D2 is, for example, 0.000310. During the period from second time point P2 to third time point P3, the propane flow rate with respect to the hydrogen flow rate may be increased at a ratio of 3.51×10⁻⁵ per minute. In this way, silicon carbide epitaxial substrate 100 having silicon carbide substrate 30 and silicon carbide epitaxial layer 40 is prepared (see FIG. 2).

When forming silicon carbide epitaxial layer 40, the silane gas and the propane gas are used. When compared at the same temperature, the propane gas has such a property that the propane gas is less likely to be decomposed than the silane gas. As a result of diligent study, the inventors have found that internal line-shaped stacking fault 10 can be effectively reduced by controlling the propane gas flow rate with respect to the temperature.

Each of carrot defect 20 and internal line-shaped stacking fault 10 is considered to be generated due to a threading screw dislocation. According to the method of manufacturing silicon carbide epitaxial substrate 100 according to the present embodiment, it is considered that the threading screw dislocation can be converted into carrot defect 20 rather than internal line-shaped stacking fault 10, thereby reducing a ratio of the number of internal line-shaped stacking faults 10 to the number of carrot defects 20.

### (Method of Manufacturing Silicon Carbide Semiconductor Device)

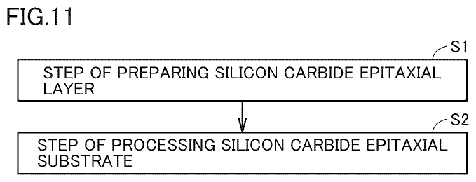

Next, a method of manufacturing a silicon carbide semiconductor device 400 according to the present embodiment will be described. FIG. 11 is a flowchart schematically showing the method of manufacturing the silicon carbide semiconductor device according to the present embodiment. As shown in FIG. 11, the method of manufacturing silicon carbide semiconductor device 400 according to the present embodiment mainly includes a step (S1) of preparing silicon carbide epitaxial substrate 100 and a step (S2) of processing silicon carbide epitaxial substrate 100.

First, the step (S1) of preparing silicon carbide epitaxial substrate 100 is performed. In the step (S1) of preparing silicon carbide epitaxial substrate 100, silicon carbide epitaxial substrate 100 according to the present embodiment is prepared (see FIG. 1).

Next, the step (S2) of processing silicon carbide epitaxial substrate 100 is performed. Specifically, the following processes are performed to silicon carbide epitaxial substrate 100. First, ion implantation is performed into silicon carbide epitaxial substrate 100.

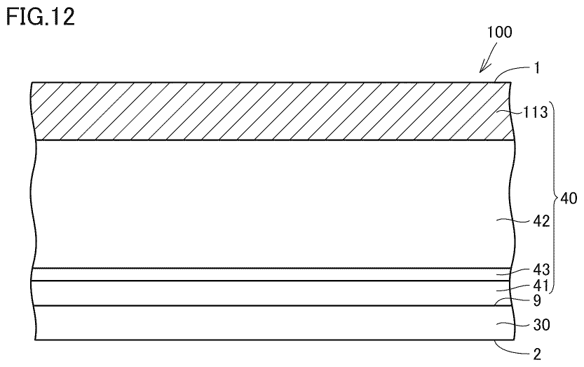

FIG. 12 is a schematic cross sectional view showing a step of forming a body region. Specifically, ion implantation of a p type impurity such as aluminum is performed into first main surface 1 of silicon carbide epitaxial layer 40. Thus, a body region 113 having p type conductivity is formed. A portion in which no body region 113 is formed serves as drift layer 42. The thickness of body region 113 is, for example, 0.9 μm.

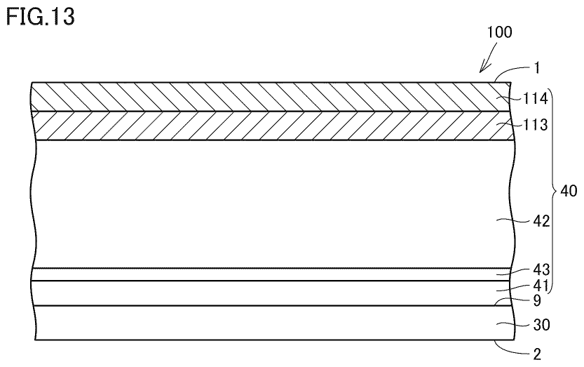

Next, a step of forming a source region is performed. FIG. 13 is a schematic cross sectional view showing the step of forming the source region. Specifically, ion implantation of an n type impurity such as phosphorus is performed into body region 113. Thus, a source region 114 having n type conductivity is formed. The thickness of source region 114 is, for example, 0.4 μm. The concentration of the n type impurity included in source region 114 is higher than the concentration of the p type impurity included in body region 113.

Next, ion implantation of a p type impurity such as aluminum is performed into source region 114 so as to form a contact region 118. Contact region 118 is formed to extend through source region 114 and body region 113 and come into contact with drift layer 42. The concentration of the p type impurity included in contact region 118 is higher than the concentration of the n type impurity included in source region 114.

Next, activation annealing is performed to activate the impurities implanted by the ion implantation. A temperature of the activation annealing is, for example, 1500° C. or more and 1900° C. or less. A time of the activation annealing is, for example, about 30 minutes. An atmosphere of the activation annealing is, for example, an argon atmosphere.

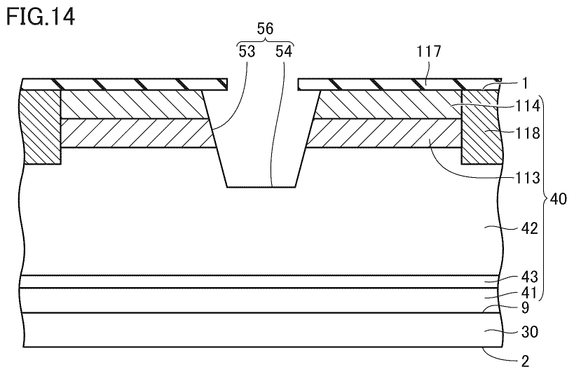

Next, a step of forming a trench in first main surface 1 of silicon carbide epitaxial layer 40 is performed. FIG. 14 is a schematic cross sectional view showing the step of forming the trench in first main surface 1 of silicon carbide epitaxial layer 40. A mask 117 provided with an opening is formed on first main surface 1 constituted of source region 114 and contact region 118. Source region 114, body region 113, and a portion of drift layer 42 are removed by etching using mask 117. As the etching method, for example, inductively coupled plasma reactive ion etching can be used. Specifically, for example, inductively coupled plasma reactive ion etching using SF₆ or a mixed gas of SF₆ and O₂ as a reaction gas is used. A recess is formed in first main surface 1 by the etching.

Next, thermal etching is performed in the recess. The thermal etching may be performed, for example, by heating in an atmosphere including a reactive gas having at least one type of halogen atom with mask 117 being formed on first main surface 1. The at least one type of halogen atom includes at least one of a chlorine (Cl) atom and a fluorine (F) atom. The atmosphere includes, for example, Cl₂, BCl₃, SF₆, or CF₄.

For example, the thermal etching is performed using a mixed gas of chlorine gas and oxygen gas as a reactive gas at a heat treatment temperature of, for example, 700° C. or more and 1000° C. or less. It should be noted that the reactive gas may include a carrier gas in addition to the chlorine gas and the oxygen gas. An exemplary, usable carrier gas is nitrogen gas, argon gas, helium gas, or the like.

As shown in FIG. 14, a trench 56 is formed in first main surface 1 by thermal etching. Trench 56 is defined by a side wall surface 53 and a bottom wall surface 54. Side wall surface 53 is constituted of source region 114, body region 113, and drift layer 42. Bottom wall surface 54 is constituted of drift layer 42. Next, mask 117 is removed from first main surface 1.

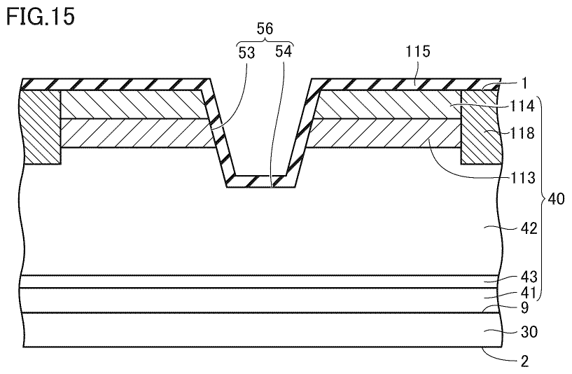

Next, a step of forming a gate insulating film is performed. FIG. 15 is a schematic cross sectional view showing the step of forming the gate insulating film. Specifically, silicon carbide epitaxial substrate 100 in which trench 56 is formed in first main surface 1 is heated in an atmosphere including oxygen at a temperature of, for example, 1300° C. or more and 1400° C. or less. Thus, a gate insulating film 115 is formed in contact with drift layer 42 at bottom wall surface 54, in contact with each of drift layer 42, body region 113, and source region 114 at side wall surface 53, and in contact with each of source region 114 and contact region 118 at first main surface 1.

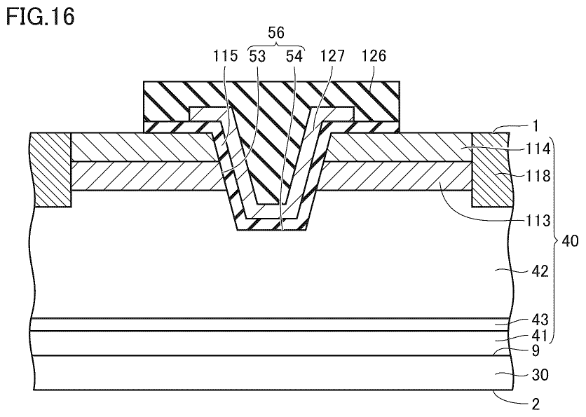

Next, a step of forming a gate electrode is performed. FIG. 16 is a schematic cross sectional view showing the step of forming the gate electrode and an interlayer insulating film. A gate electrode 127 is formed inside trench 56 so as to be in contact with gate insulating film 115. Gate electrode 127 is disposed inside trench 56, and is formed on gate insulating film 115 so as to face each of side wall surface 53 and bottom wall surface 54 of trench 56. Gate electrode 127 is formed by, for example, an LPCVD (Low Pressure Chemical Vapor Deposition) method.

Next, an interlayer insulating film 126 is formed. Interlayer insulating film 126 is formed to cover gate electrode 127 and be in contact with gate insulating film 115. Interlayer insulating film 126 is formed by, for example, a chemical vapor deposition method. Interlayer insulating film 126 is composed of, for example, a material including silicon dioxide. Next, portions of interlayer insulating film 126 and gate insulating film 115 are etched to form an opening above source region 114 and contact region 118. Thus, contact region 118 and source region 114 are exposed from gate insulating film 115.

Next, a step of forming a source electrode is performed. A source electrode 116 is formed in contact with each of source region 114 and contact region 118. Source electrode 116 is formed by, for example, a sputtering method. Source electrode 116 is composed of, for example, a material including Ti (titanium), Al (aluminum), and Si (silicon).

Next, alloying annealing is performed. Specifically, source electrode 116 in contact with each of source region 114 and contact region 118 is held at a temperature of, for example, 900° C. or more and 1100° C. or less for about 5 minutes. Thus, at least a portion of source electrode 116 is silicided. In this way, source electrode 116 in ohmic contact with source region 114 is formed. Source electrode 116 may be in ohmic contact with contact region 118.

Next, a source wiring 119 is formed. Source wiring 119 is electrically connected to source electrode 116. Source wiring 119 is formed to cover source electrode 116 and interlayer insulating film 126.

Next, a step of forming a drain electrode is performed. First, second main surface 2 of silicon carbide substrate 30 is polished. Thus, the thickness of silicon carbide substrate 30 is reduced. Next, a drain electrode 123 is formed. Drain electrode 123 is formed in contact with second main surface 2. In this way, silicon carbide semiconductor device 400 according to the present embodiment is manufactured.

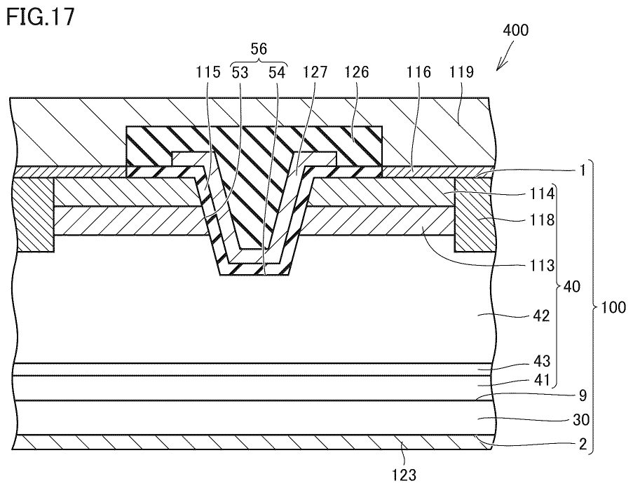

FIG. 17 is a schematic cross sectional view showing a configuration of the silicon carbide semiconductor device according to the present embodiment. Silicon carbide semiconductor device 400 is, for example, a MOSFET (Metal Oxide Semiconductor Field Effect Transistor). Silicon carbide semiconductor device 400 mainly has silicon carbide epitaxial substrate 100, gate electrode 127, gate insulating film 115, source electrode 116, drain electrode 123, source wiring 119, and interlayer insulating film 126. Silicon carbide epitaxial substrate 100 has drift layer 42, body region 113, source region 114, and contact region 118. Silicon carbide semiconductor device 400 may be, for example, an IGBT (Insulated Gate Bipolar Transistor) or the like.

Next, functions and effects of silicon carbide epitaxial substrate 100 and the silicon carbide semiconductor device according to the present embodiment will be described.

When carrot defect 20 exists in silicon carbide epitaxial substrate 100, carrot defect 20 can be readily detected as a surface defect because a protruding portion is formed in carrot defect 20. Further, coverage of the gate oxide film formed on carrot defect 20 is deteriorated. As a result, a gate leakage current is generated in a semiconductor element formed in the region in which carrot defect 20 exists. In many cases, such a semiconductor element formed in the region in which carrot defect 20 exists is determined as being non-conforming in terms of breakdown voltage or the like in an initial property inspection at a wafer stage. The semiconductor element determined as being non-conforming in terms of breakdown voltage is classified as a non-conforming product and is therefore not normally shipped out.

On the other hand, when internal line-shaped stacking fault 10 exists in silicon carbide epitaxial substrate 100, it is difficult to detect internal line-shaped stacking fault 10 as a surface defect because no protruding portion is formed above internal line-shaped stacking fault 10. Further, coverage of the gate oxide film formed on silicon carbide epitaxial layer 40 including internal line-shaped stacking fault 10 therein is not deteriorated so much. Therefore, a semiconductor element formed in the region having internal line-shaped stacking fault 10 may pass the initial property inspection. The semiconductor element having passed the initial property inspection may be subjected to various post processes such as a wafer dicing process, and may be shipped out as a semiconductor device.

However, such a semiconductor device including internal line-shaped stacking fault 10 may cause property deterioration (reliability failure) during operation. Therefore, it is desirable to reduce internal line-shaped stacking fault 10.

According to silicon carbide epitaxial substrate 100 according to the present disclosure, the number of internal line-shaped stacking faults 10 is less than the number of carrot defects 20. Thus, it is possible to suppress formation of a silicon carbide semiconductor device that would have otherwise caused reliability failure after shipment. The carrot defect can be readily inspected from the surface, and results in a poor initial property. Therefore, all the devices including such carrot defects can be determined as being non-conforming products at the time of shipment. On the other hand, since internal line-shaped stacking fault 10 has a small influence on the initial property and does not appear at the surface, internal line-shaped stacking fault 10 is not readily detected. Therefore, a device including such an internal line-shaped stacking fault 10 may be determined as being a conforming product at the time of shipment.

### Examples

### (Preparation of Samples)

First, silicon carbide epitaxial substrates 100 according to samples 1 to 5 were prepared. Silicon carbide epitaxial substrates 100 according to samples 1 and 2 are comparative examples. Silicon carbide epitaxial substrates 100 according to samples 3 to 5 are examples of the present disclosure. Each of silicon carbide epitaxial substrates 100 according to samples 1 to 5 had a diameter of 150 mm.

Each of silicon carbide epitaxial substrates 100 according to samples 1 to 5 was manufactured in accordance with the method described in FIGS. 9 and 10. Specifically, silicon carbide epitaxial substrate 100 was manufactured using conditions shown in Table 1.

TABLE 1

| | | Buffer Layer | Transition Layer | Drift Layer |
|---|---|---|---|---|
| Samples | Temperature (° C.) | 1605 | 1605→1720 | 1720 |
| 1 and 2 | H₂ Flow Rate (slm) | 134 | 134 | 134 |
| | SiH₄ Flow Rate (sccm) | 57.5 | 57.5→96 | 96 |
| | C₃H₈ Flow Rate (sccm) | 18 | 18→54.5 | 54.5 |
| | Time (min.) | 20 | 8 | 60 |
| | C₃H₈ Flow Rate/H₂ Flow | 0.000134 | 3.40 × 10⁻⁵ (/min.) | 0.000407 |
| | Rate | | | |
| | 3 × C₃H₈ Flow Rate/ | 0.034 | 0.0077(/min.) | 0.095 |
| | Temperature (sccm/° C.) | | | |
| Samples | Temperature (° C.) | 1575 | 1575→1692 | 1692 |
| 3 to 5 | H₂ Flow Rate (slm) | 134 | 134 | 134 |
| | SiH₄ Flow Rate (sccm) | 57.5 | 57.5→80 | 80 |
| | C₃H₈ Flow Rate (sccm) | 18 | 18→41.5 | 41.5 |
| | Time (min.) | 20 | 5 | 60 |
| | C₃H₈ Flow Rate/H₂ Flow | 0.000134 | 3.51 × 10⁻⁵ (/min.) | 0.000310 |
| | Rate | | | |
| | 3 × C₃H₈ Flow Rate/ | 0.034 | 0.0079(/min.) | 0.074 |
| | Temperature (sccm/° C.) | | | |

Each of silicon carbide epitaxial substrates 100 according to samples 1 and 2 was manufactured as follows.

During the period from first time point P1 to second time point P2, a temperature of reaction chamber 201 was set to 1605° C. During the period from second time point P2 to third time point P3, the temperature was increased from 1605° C. to 1720° C. During the period from third time point P3 to fourth time point P4, the temperature was set to 1720° C. During the period from first time point P1 to fourth time point P4, the H₂ flow rate was set to 134 slm.

During the period from first time point P1 to second time point P2, the SiH₄ flow rate was set to 57.5 sccm. During the period from second time point P2 to third time point P3, the SiH₄ flow rate was increased from 57.5 sccm to 96 sccm. During the period from third time point P3 to fourth time point P4, the SiH₄ flow rate was set to 96 sccm.

During the period from first time point P1 to second time point P2, the C₃H₈ flow rate was set to 18 sccm. During the period from second time point P2 to third time point P3, the C₃H₈ flow rate was increased from 18 sccm to 54.5 sccm. During the period from third time point P3 to fourth time point P4, the C₃H₈ flow rate was set to 54.5 sccm.

The period from first time point P1 to second time point P2 was 20 minutes. The period from second time point P2 to third time point P3 was 8 minutes. The period from third time point P3 to fourth time point P4 was 60 minutes.

During the period from first time point P1 to second time point P2, the C₃H₈ flow rate/the H₂ flow rate was 0.000134. During the period from second time point P2 to third time point P3, the C₃H₈ flow rate/the H₂ flow rate was increased at a ratio of 3.40×10⁻⁵ per minute. During the period from third time point P3 to fourth time point P4, the C₃H₈ flow rate/the H₂ flow rate was 0.000407.

During the period from first time point P1 to second time point P2, 3×the C₃H₈ flow rate/the temperature (sccm/° C.) was 0.034. During the period from second time point P2 to third time point P3, 3 ×the C₃H₈ flow rate/the temperature (sccm/° C.) was increased at a ratio of 0.0077 per minute. During the period from third time point P3 to fourth time point P4, 3×the C₃H₈ flow rate/the temperature (sccm/° C.) was 0.095.

Each of silicon carbide epitaxial substrates 100 according to samples 3 to 5 was manufactured as follows.

During the period from first time point P1 to second time point P2, the temperature was set to 1575° C. During the period from second time point P2 to third time point P3, the temperature was increased from 1575° C. to 1692° C. The temperature was set to 1692° C. during the period from third time point P3 to fourth time point P4. During the period from first time point P1 to fourth time point P4, the H₂ flow rate was set to 134 slm.

During the period from first time point P1 to second time point P2, the SiH₄ flow rate was set to 57.5 sccm. During the period from second time point P2 to third time point P3, the SiH₄ flow rate was increased from 57.5 sccm to 80 sccm. During the period from third time point P3 to fourth time point P4, the SiH₄ flow rate was set to 80 sccm.

During the period from first time point P1 to second time point P2, the C₃H₈ flow rate was set to 18 sccm. During the period from second time point P2 to third time point P3, the C₃H₈ flow rate was increased from 18 sccm to 41.5 sccm. During the period from third time point P3 to fourth time point P4, the C₃H₈ flow rate was set to 41.5 sccm.

The period from first time point P1 to second time point P2 was 20 minutes. The period from second time point P2 to third time point P3 was 5 minutes. The period from third time point P3 to fourth time point P4 was 60 minutes.

During the period from first time point P1 to second time point P2, the C₃H₈ flow rate/the H₂ flow rate was 0.000134. During the period from second time point P2 to third time point P3, the C₃H₈ flow rate/the H₂ flow rate was increased at a ratio of 3.51×10⁻⁵ per minute. During the period from third time point P3 to fourth time point P4, the C₃H₈ flow rate/the H₂ flow rate was 0.000310.

During the period from first time point P1 to second time point P2, 3×the C₃H₈ flow rate/the temperature (sccm/° C.) was 0.034. During the period from second time point P2 to third time point P3, 3 ×the C₃H₈ flow rate/the temperature (sccm/° C.) was increased at a ratio of 0.0079 per minute. During the period from third time point P3 to fourth time point P4, 3 ×the C₃H₈ flow rate/the temperature (sccm/° C.) was 0.074.

### Experiment Method

First main surface 1 of silicon carbide epitaxial substrate 100 according to each of samples 1 to 5 was imaged using a PL imaging device (SemiScope PLI-200) provided by PHOTON Design Corporation. The number of internal line-shaped stacking faults 10 and the number of carrot defects 20 in first main surface 1 were found. A mercury xenon lamp was used as light source unit 221. The wavelength of excitation light LE is 313 nm. The magnification of near-infrared objective lens 333 was set to 4.5 times. The measurement temperature was a room temperature (27° C.). Color image sensor 335 was a CCD (charge-coupled device) image sensor.

The CCD element was of a back-illuminated deep depletion type. The CCD image sensor was, for example, excelon (trademark) provided by Teledyne. An imaging wavelength range is 310 nm or more and 1024 nm or less. An element format is 1024ch'1024ch. An image area is 13.3 mm×13.3 mm. An element size is 13 μm×13 μm.

### Experiment Result

TABLE 2

| | Internal Line-Shaped | Carrot | Internal Line-Shaped |
|---|---|---|---|
| | Stacking Fault | Defect | Stacking Fault/ |
| | (Number) | (Number) | Carrot Defect |
| Sample 1 | 21 | 13 | 1.62 |
| Sample 2 | 26 | 19 | 1.37 |
| Sample 3 | 149 | 272 | 0.55 |
| Sample 4 | 26 | 90 | 0.29 |
| Sample 5 | 6 | 59 | 0.10 |

Table 2 shows the number of internal line-shaped stacking faults 10 and the number of carrot defects 20 in silicon carbide epitaxial substrate 100, as well as a value obtained by dividing the number of internal line-shaped stacking faults 10 by the number of carrot defects 20.

As shown in Table 2, the number of internal line-shaped stacking faults 10 and the number of carrot defects 20 in silicon carbide epitaxial substrate 100 of sample 3 are respectively larger than the number of internal line-shaped stacking faults 10 and the number of carrot defects 20 in silicon carbide epitaxial substrate 100 of sample 5. The number of internal line-shaped stacking faults 10 and the number of carrot defects 20 are increased as the number of threading screw dislocations in silicon carbide substrate 30 is increased. Therefore, even though the same manufacturing method is used, the numbers of internal line-shaped stacking faults 10 and the numbers of carrot defects 20 are greatly different.

As shown in Table 2, in silicon carbide epitaxial substrate 100 of each of the comparative examples, the number of internal line-shaped stacking faults 10 was more than the number of carrot defects 20. On the other hand, in silicon carbide epitaxial substrate 100 of each of the examples of the present disclosure, the number of internal line-shaped stacking faults 10 was less than the number of carrot defects 20. In view of the above results, in silicon carbide epitaxial substrate 100 of each of the examples of the present disclosure, the number of internal line-shaped stacking faults 10 can be less than the number of carrot defects 20 regardless of the number of internal line-shaped stacking faults 10 and the number of carrot defects 20.

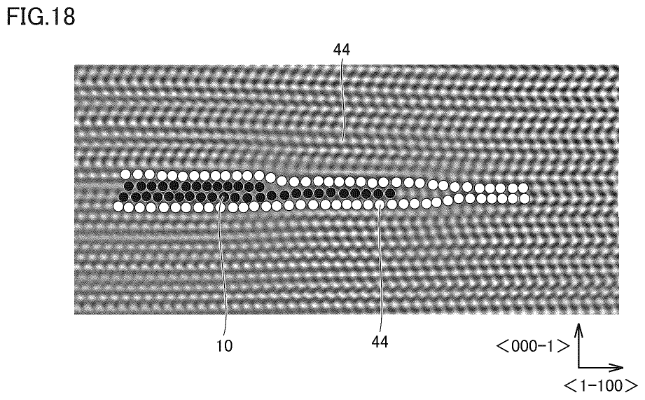

FIG. 18 is a transmission electron microscope (TEM) image of the silicon carbide epitaxial substrate according to the example of the present disclosure. A portion shown along black dots in FIG. 18 is disposed along atoms of internal line-shaped stacking fault 10. Internal line-shaped stacking fault 10 extends along first direction 101. A portion shown along white dots in FIG. 18 is disposed along atoms of the region having a polytype of 4H. As shown in FIG. 18, internal line-shaped stacking fault 10 is sandwiched by region 44 having a polytype of 4H in third direction 103. As shown in FIG. 18, internal line-shaped stacking fault 10 may be two atomic layers.

The embodiments and examples disclosed herein are illustrative and non-restrictive in any respect. The scope of the present invention is defined by the terms of the claims, rather than the embodiments and examples described above, and is intended to include any modifications within the scope and meaning equivalent to the terms of the claims.

### REFERENCE SIGNS LIST

1: main surface (first main surface); 2: second main surface; 3: orientation flat; 4: arc-shaped portion; 5: outer peripheral edge; 6: fourth main surface; 9: third main surface; 10: internal line-shaped stacking fault; 11: first end portion; 12: second end portion; 13: third end portion; 14: fourth end portion; 15: upper end surface; 20: carrot defect; 21: apex portion; 22: bottom side portion; 23: first side portion; 24: second side portion; 25: bottom surface portion; 26: side surface portion; 30: silicon carbide substrate; 40: silicon carbide epitaxial layer; 41: buffer layer; 42: drift layer; 43: transition layer; 44: region; 53: side wall surface; 54: bottom wall surface; 56: trench; 100: silicon carbide epitaxial substrate; 101: first direction; 102: second direction; 103: third direction; 104: fourth direction; 110: threading screw dislocation; 111: first threading screw dislocation; 112: second threading screw dislocation; 113: body region; 114: source region; 115: gate insulating film; 116: source electrode; 117: mask; 118: contact region; 119: source wiring; 123: drain electrode; 126: interlayer insulating film; 127: gate electrode; 200: color photoluminescence imaging device; 201: reaction chamber; 202, 332: stage; 203: heating element; 204: quartz tube; 205: inner wall surface; 207: gas introduction port; 208: gas discharging port; 209: rotation shaft; 210: susceptor; 220: excitation light generation unit; 221: light source unit; 222: light guide unit; 223: filter unit; 230: imaging unit; 231: first gas supply unit; 232: second gas supply unit; 233: third gas supply unit; 234: fourth gas supply unit; 235: gas supply unit; 241: first gas flow rate control unit; 242: second gas flow rate control unit; 243: third gas flow rate control unit; 244: fourth gas flow rate control unit; 245, 331: control unit; 300: manufacturing apparatus; 333: near-infrared objective lens; 335: color image sensor; 400: silicon carbide semiconductor device; A1: first width; A2: second width; B1: first length; B2: second length; B3: third length; C1: first ratio; C2: second ratio; D1: third ratio; D2: fourth ratio; E2: distance; LE: excitation light; LL: photoluminescence light; P1: first time point; P2: second time point; P3: third time point; P4: fourth time point; W1: maximum diameter; θ: off angle.

1. A silicon carbide epitaxial substrate comprising:
a silicon carbide substrate;
a silicon carbide epitaxial layer located on the silicon carbide substrate and having a main surface;
an internal line-shaped stacking fault located inside the silicon carbide epitaxial layer and separated from the main surface; and
a carrot defect exposed at the main surface, wherein
the main surface is a plane inclined with respect to a {0001} plane, and
when a length of the carrot defect in a <1-100> direction is defined as a first length, a width of the carrot defect in a <11-20> direction is defined as a first width, a length of the internal line-shaped stacking fault in the <1-100> direction is defined as a second length, and a width of the internal line-shaped stacking fault in the <11-20> direction is defined as a second width as viewed in a direction perpendicular to the main surface,
a value obtained by dividing the first length by the first width is more than 0.5,
a value obtained by dividing the second length by the second width is 0.5 or less, and
the number of the internal line-shaped stacking faults is less than the number of the carrot defects.

2. The silicon carbide epitaxial substrate according to claim 1, wherein when photoluminescence light generated from the internal line-shaped stacking fault by applying excitation light to the internal line-shaped stacking fault is expressed in an HSV color space, H is 150° or more and 220° or less, S is 30 or more and 100 or less, and V is 205 or more and 255 or less.

3. The silicon carbide epitaxial substrate according to claim 1, wherein when photoluminescence light generated from the carrot defect by applying excitation light to the carrot defect is expressed in an HSV color space, H is 80° or more and 235° or less, S is 25 or more and 90 or less, and V is 180 or more and 255 or less.

4. The silicon carbide epitaxial substrate according to claim 1, wherein a value obtained by dividing the number of the internal line-shaped stacking faults by the number of the carrot defects is 0.55 or less.

5. The silicon carbide epitaxial substrate according to claim 1, wherein the main surface is a plane inclined with respect to a (000-1) plane.

6. The silicon carbide epitaxial substrate according to claim 5, wherein an off angle of the main surface with respect to the (000-1) plane is more than 0° and 8° or less.

7. The silicon carbide epitaxial substrate according to claim 1, wherein
the internal line-shaped stacking fault extends in a form of a line from a first end portion toward a second end portion opposite to the first end portion as viewed in the direction perpendicular to the main surface, and
a length of the first end portion in the <1-100> direction is 0.8 times or more and 1.2 times or less as large as a length of the second end portion in the <1-100> direction.

8. The silicon carbide epitaxial substrate according to claim 1, wherein when measured by a white light microscope, a step of a portion of the main surface that the internal line-shaped stacking fault faces is 9 nm or less.

9. The silicon carbide epitaxial substrate according to claim 1, wherein
the internal line-shaped stacking fault has an upper end surface facing the main surface, and
a distance between the main surface and the upper end surface is 0.1 μm or more in the direction perpendicular to the main surface.

10. The silicon carbide epitaxial substrate according to claim 9, wherein a region between the main surface and the upper end surface is a region having a polytype of 4H.

11. The silicon carbide epitaxial substrate according to claim 1, wherein the internal line-shaped stacking fault includes a Frank-type fault.

12. The silicon carbide epitaxial substrate according to claim 1, wherein the silicon carbide epitaxial layer has a polytype of 4H.

13. A method of manufacturing a silicon carbide semiconductor device, the method comprising:
preparing the silicon carbide epitaxial substrate according to claim 1; and
processing the silicon carbide epitaxial substrate.
